(19) United States
(12) Patent Application Publication
(10) Pub. No.: US 2017/0084832 A1
(43) Pub. Date: Mar. 23, 2017

(54) NON-VOLATILE RESISTANCE SWITCHING DEVICES

(71) Applicant: The Trustees of The University of Pennsylvania, Philadelphia, PA (US)

(72) Inventors: I-Wei CHEN, Swarthmore, PA (US); Yang LU, Wynnewood, PA (US)

(21) Appl. No.: 15/312,196

(22) PCT Filed: May 21, 2015
(86) PCT No.: PCT/US2015/031889

§ 371 Date: Nov. 18, 2016

Related U.S. Application Data
(60) Provisional application No. 62/001,374, filed on May 21, 2014.

(51) Int. Cl. H01L 45/00

(52) U.S. Cl. CPC H01L 45/06; H01L 45/147; H01L 45/141; H01L 45/1625

(57) ABSTRACT

The present disclosure provides, inter alia, amorphous materials useful in electronic devices such as memory devices. In some embodiments, these materials include a semiconductor having an electronegative element doped within. The present invention may b understood more readily by reference to the following detailed description taken in connection with the accompanying figures and examples, which form a part of this disclosure. It is to be understood that this invention is not limited to the specific devices, methods, applications, conditions or parameters described and/or shown herein, and that the terminology used herein is for the purpose of describing particular embodiments by way of example only and is not intended to be limiting of the claimed invention.

### RELATED APPLICATION

The present application claims priority to and the benefit of U.S. Patent Application No. 62/001,374, “Non-Volatile Resistance Switching Devices,” filed May 21, 2014, the entirety of which application is incorporated herein for any and all purposes.

### STATEMENT OF GOVERNMENT RIGHTS

This work was supported by National Science Foundation (NSF) grants DMR-11-04530, DMR-09-07523, and DMR-11-20901. The government has certain rights in this invention.

### TECHNICAL FIELD

The present disclosure relates to the field of semiconducting materials and to the field of memory devices.

### BACKGROUND

In the field of electronic devices, there is a long-felt need for non-volatile resistance switching devices. The value of such devices would be enhanced if the devices could function in a resistive and/or capacitive ways.

### SUMMARY

Provided here are amorphous semiconducting thin films useful in, inter alia, non-volatile memory devices; the films undergo a conductor-insulator transition after addition of electronegative dopants (or other insulating compositions containing electronegative dopants). This addition of dopants can be simply achieved by slight oxidation or nitridation of the amorphous semiconductor film. This behavior is unexpected, as there is no precedent for making a semiconductor into a conducting material via addition of electronegative elements, e.g., oxygen or nitrogen. In fact, it is generally expected that addition of electronegative elements, e.g., oxygen or nitrogen, makes a semiconductor into a less conducting material.

This disclosure expands the universe of materials that exhibit thickness-and voltage-dependent conductor-insulator transition in an entirely unexpected way. Existing materials achieved this behavior by adding a conducting species into an insulating species. By contrast, the disclosed technology achieves this by adding an insulating species (e.g., an electronegative element) into a semiconducting species. As one illustrative example, the disclosed compositions may be obtained by mixing O or N into Si, or by mixing an insulating oxide (such as Al₂O₃ or HfO₂) or insulating nitride (such as Si₃N₄ or MN) into Si. The present disclosure embraces at least the following exemplary compositions, in turn making the disclosed technology compatible with current CMOS technology and making the disclosed technology especially valuable.

These exemplary compositions are: (a) undoped, n-type-doped, or p-type-doped silicon and germanium, which cover main group IV elemental semiconductors, (b) silicon carbide, gallium arsenide, gallium nitride, indium phosphide, indium arsenide and zinc sulfide, which cover main group IV, main group III-V and main group II-VI compound semiconductors; used as the majority amorphous semiconductor, along with the following: (c) yttrium oxide, hafnium oxide and tantalum oxide, which cover transition metal oxides and rare earth oxides, (d) magnesium oxide, aluminum oxide and aluminum nitride, which cover main group II and main group III metal oxides and nitrides and (e) silicon oxide, silicon nitride and germanium oxide, which cover main group IV insulator oxides and nitrides; used as the minority amorphous insulator.

In one aspect, the present disclosure provides devices comprising an amorphous resistance-switching layer comprising: an electrically semiconducting composition; and one or more electronegative elements disposed within the electrically semiconducting composition, the layer having a cross-sectional dimension in the range of about 0.5 nm to about 60 nm; and at least one electrode in electronic communication with the amorphous layer.

The present disclosure also provides methods, the methods comprising disposing, on a substrate, a semiconducting material and one or more electronegative elements such that the semiconducting material and the one or more electronegative elements form an amorphous layer, the layer having a cross-sectional dimension in the range of from about 0.5 nm to about 60 nm.

Additionally disclosed methods include, e.g., placing a layer of semiconducting material into contact (e.g., via forming, depositing, or otherwise disposing) with a second layer of material that comprises an electronegative element; and effecting disposition of at least some of the electronegative elements within the layer of semiconducting material, forming an amorphous layer.

Further provided are methods, comprising contacting an electrode that comprises an electronegative element with a layer of semiconducting material; and effecting disposition of at least some of the electronegative elements within the layer of semiconducting material, forming an amorphous layer.

The present disclosure further provides methods that comprise, inter alia, placing a layer of semiconducting material into contact with a second layer of material that comprises an electronegative element (e.g., by disposing, forming, depositing, or via other methods); and effecting disposition of at least some of the electronegative elements within the layer of semiconducting material, forming an amorphous layer.

Other disclosed methods include contacting an electrode that comprises an electronegative element with a layer of semiconducting material; and effecting disposition of at least some of the electronegative elements within the layer of semiconducting material, forming an amorphous layer.

Further provided are amorphous semiconducting thin films useful in, inter alia, non-volatile memory devices; the films undergo a conductor-insulator transition after addition of electronegative dopants (or other insulating compositions containing electronegative dopants). This addition of dopants can be simply achieved by slight oxidation or nitridation of the amorphous semiconductor film. This behavior is surprising because of the lack of precedent for making a semiconductor into a conducting material via addition of electronegative elements, e.g., oxygen or nitrogen. Instead, it is generally expected that addition of electronegative elements, e.g., oxygen or nitrogen, makes a semiconductor into a less conducting material.

### SUMMARY

This disclosure expands the universe of materials that exhibit thickness-and voltage-dependent conductor-insulator transition in an entirely unexpected way. Existing materials achieved this behavior by adding a conducting species into an insulating species. By contrast, the disclosed technology achieves this by adding an insulating species (e.g., an electronegative element) into a semiconducting species. As one illustrative example, the disclosed compositions may be obtained by mixing O or N into Si, or by mixing an insulating oxide (such as Al₂O₃ or HfO₂) or insulating nitride (such as Si₃N₄ or AlN) into Si. The present disclosure embraces at least the following exemplary compositions, in turn making the technology entirely compatible with current CMOS technology and making the technology especially valuable.

These exemplary compositions are: (a) undoped, n-type-doped, or p-type-doped silicon and germanium, which cover main group IV elemental semiconductors, and (b) silicon carbide, gallium arsenide, gallium nitride, indium phosphide, indium arsenide, and zinc sulfide, which cover main group IV, main group III-V and main group II-VI compound semiconductors; used as the majority amorphous semiconductor, along with the following: (c) yttrium oxide, hafnium oxide and tantalum oxide, which cover transition metal oxides and rare earth oxides, (d) magnesium oxide, aluminum oxide and aluminum nitride, which cover main group II and main group III metal oxides and nitrides and (e) silicon oxide, silicon nitride and germanium oxide, which cover main group IV insulator oxides and nitrides; used as the minority amorphous insulator.

By mixing these majority amorphous semiconductors and minority amorphous insulators in any number of ways, in suitable proportions, the resulting thin films of suitable thickness form robust non-volatile memory, switching between a highly conducting state and a highly insulating state at small and reproducible voltages. The above compositions include all the commonly used semiconductors and all the commonly used dielectrics/insulators. This expanded universe of materials is of immediate utility to the electronics industry, as the disclosed materials offer opportunities and flexibility for design, processing, and fabrication.

At present, non-volatile resistance memory is the focus of memory research of electronic industry worldwide. Existing technologies require the use of metals (conductors) for use in memory. Utilizing amorphous semiconductor thin films without the need for metal incorporation significantly decreases material and fabrication costs, and increase the CMOS design and fabrication compatibility. The present disclosure provides the manufacture and use of amorphous semiconductors, doped with insulators, for non-volatile resistance memory applications.

Compared to existing alternatives, the present disclosure provides at least the following advantages:

Complete CMOS compatibility: The present compositions, such as Si:O, Si:N, Si:(O,N), Si:SiO₂, Si:Al₂O₃, Si:HfO₂, Si:Si₃N₄, Si:AlN, Si:((Si,Al)(O,N)), etc., wherein, Si:O is a binary mixture composition between Si and O (this composition is also expressed as SiOₓ or Si[Oₓ] in the following, and these expressions are equivalent and interchangeable; likewise for other similar expressions), and Si:Si₃N₄ is a binary composition between Si and Si₃N₄, etc. (this composition is also expressed as Si—Si₃N₄, Si—SiN_{4/3}, or Si[N_{4x/3}Siₓ] in the following, and these expressions are interchangeable; likewise for other similar expressions), are completely CMOS compatible, both in composition and processing. There is no need to introduce a separate species such as a metal.

Complete solution and miscibility: Previous compositions, comprising a mixture of insulator and metal, are not miscible, in that the metal is not soluble in the insulator and they were merely physically mixed, albeit at the atomic level. The present compositions, e.g., Si:O, Si:N, Si:(O,N), Si:SiO₂, Si:Al₂O₃, Si:HfO₂, Si:Si₃N₄, Si:AlN, Si:((Si,Al)(O,N)), etc., are completely miscible and thus reduce the concern for clustering (which may happen to metal atoms that are immiscible in the insulator matrix). This in turns means that the disclosed mixtures are more uniform than existing alternatives. As a result, one may form devices that are thinner and have a smaller area than before.

### BRIEF DESCRIPTION OF THE DRAWINGS

The summary, as well as the following detailed description, is further understood when read in conjunction with the appended drawings. For the purpose of illustrating the invention, there are shown in the drawings exemplary embodiments of the invention; however, the invention is not limited to the specific methods, compositions, and devices disclosed. In addition, the drawings are not necessarily drawn to scale. Applicants note that they have filed drawings in color for the reader's convenience. In the drawings:

FIG. 1 shows X-ray diffraction spectra of several thin film samples on silicon substrate, along with the spectrum (Si Sub) of the silicon substrate, a (100) oriented single crystal. Pt film (Pure Pt), AlO_{3/2} film (Pure AlO_{3/2}), Si film (Pure Si), mixed Si and AlO_{3/2} film (Si:AlO_{3/2}). All spectra reveal the Si (100) peak of the substrate underneath because the films are thin and X-ray is penetrating. The Pt film has additional diffraction peaks, of (111), (200) and (311) because the film is crystalline. All other films have identical spectrum as the substrate, indicating they provide no additional diffraction peak because they are amorphous.

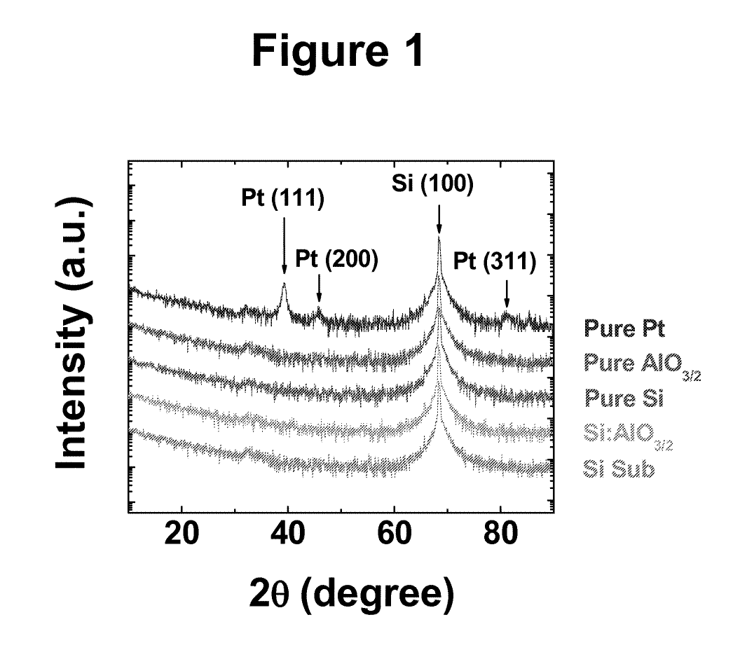

FIG. 2 shows exemplary I-V and R-V curves of one embodiment of the present invention using amorphous SiNₓ (with Si as the semiconducting composition and N as the electronegative dopant), with the combination of Mo and Pt electrodes.

FIG. 3 shows exemplary I-V and R-V curves of one embodiment of the present invention using SiOₓ (with Si as the semiconducting composition and O as the electronegative dopant), with the combination of Ti and Pt electrodes.

FIG. 4 shows exemplary I-V and R-V curves of one embodiment of the present invention using Si—SiN_{4/3} (with Si as the semiconducting composition and SiN_{4/3} as the insulating composition), wherein Si—SiN_{4/3} is a binary mixture composition between Si and SiN_{4/3}, with the combination of Mo and Pt electrodes.

FIG. 5 shows exemplary I-V and R-V curves of one embodiment of the present invention using Si—SiO₂ (with Si as the semiconducting composition and SiO₂ as the insulating composition), wherein Si—SiO₂ is a binary mixture composition between Si and SiO₂, with the combination of Mo and Pt electrodes.

FIG. 6 shows exemplary I-V and R-V curves of one embodiment of the present invention using Si—AlN (with Si as the semiconducting composition and AlN as the insulating composition), wherein Si—AlN is a binary mixture composition between Si and AlN, with the combination of Mo and Pt electrodes.

FIG. 7 shows exemplary I-V and R-V curves of one embodiment of the present invention using Si—AlO_{3/2} (with Si as the semiconducting composition and AlO_{3/2} as the insulating composition), wherein Si—AlO_{3/2} is a binary mixture composition between Si and AlO_{3/2}, with the combination of Mo and Pt electrodes.

FIG. 8 shows exemplary I-V and R-V curves of one embodiment of the present invention using Si-HfO₂ (with Si as the semiconducting composition and HfO₂ as the insulating composition), wherein Si-HfO₂ is a binary mixture composition between Si and HfO₂, with the combination of Mo and Pt electrodes.

FIG. 9 shows exemplary I-V and R-V curves of one embodiment of the present invention using Ge—SiN_{4/3} (with Ge as the semiconducting composition and SiN_{4/3} as the insulating composition), wherein Ge—SiN_{4/3} is a binary mixture composition between Ge and SiN_{4/3}, with the combination of Mo and Pt electrodes.

FIG. 10 shows exemplary I-V and R-V curves of one embodiment of the present invention using (SiC)Oₓ (with SiC as the semiconducting composition and O as the electronegative dopant), with the combination of Mo and Pt electrodes.

FIG. 11 shows exemplary I-V and R-V curves of one embodiment of the present invention using SiOₓ (with Si as the semiconducting composition and O as the electronegative dopant), with one additional thin insulating layer of AlO_{3/2}, with the combination of Ti and Pt electrodes.

FIG. 12 shows exemplary I-V and R-V curves of one embodiment of the present invention using SiOₓ (with Si as the semiconducting composition and O as the electronegative dopant), with additional thin semiconducting layers of Si in contact with Ti and Pt electrodes.

FIG. 13 shows 20 consecutive R-V curves of one embodiment of the present invention using Si—AlO_{3/2} (with Si as the semiconducting composition and AlO_{3/2} as the insulating composition), wherein Si—AlO_{3/2} is a binary mixture composition between Si and AlO_{3/2}, with the combination of Mo and Pt electrodes. Good reproducibility of two states is demonstrated.

FIG. 14 shows multiple resistance states (0 to 4) are achieved by varying voltage using Si—AlO_{3/2}.

FIG. 15(a) shows the data retention of three states achieved in a Si—AlO_{3/2} memory device. Each state is stable and non-volatile for data storage. FIG. 15(b) shows the corresponding R-V curves.

FIG. 16 shows the comparison of C—V dependence in two resistance states (High resistance state: HRS, and low resistance state: LRS) in two memory samples. “Type A” sample comprises an amorphous layer of Si lightly doped by SiN_{4/3} and “type B” sample comprises an amorphous layer of Si heavily doped by SiN_{4/3}. These two types of memory samples are distinguishable by the ratio of the capacitance of the low resistance state (LRS) to the capacitance of the high resistance state (HRS): type B memory has a ratio very close to 1, type A memory has a ratio significantly below 1. Such distinctly different non-volatile capacitances of the two states provide another means of storing memory.

FIG. 17 depicts an illustrative map of thickness (δ)-oxygen composition combinations (x as in SC[Oₓ], where SC is the semiconducting composition) for rendering switching device using amorphous Si—AlO_{3/2} mixture layer. Si is the semiconducting composition, AlO_{3/2} is the insulating composition that supplies electronegative dopant O. Films of large thickness are insulting, films of thin thickness are conducting. Films of intermediate thickness are either semiconducting or switching depending on x. Among the switching films, type A switching occurs at smaller x, and type B at larger x.

### DETAILED DESCRIPTION OF ILLUSTRATIVE EMBODIMENTS

The present invention may be understood more readily by reference to the following detailed description taken in connection with the accompanying figures and examples, which form a part of this disclosure. It is to be understood that this invention is not limited to the specific devices, methods, applications, conditions or parameters described and/or shown herein, and that the terminology used herein is for the purpose of describing particular embodiments by way of example only and is not intended to be limiting of the claimed invention. Also, as used in the specification including the appended claims, the singular forms “a,” “an,” and “the” include the plural, and reference to a particular numerical value includes at least that particular value, unless the context clearly dictates otherwise. The term “plurality”, as used herein, means more than one. When a range of values is expressed, another embodiment includes from the one particular value and/or to the other particular value. Similarly, when values are expressed as approximations, by use of the antecedent “about,” it will be understood that the particular value forms another embodiment. All ranges are inclusive and combinable.

It is to be appreciated that certain features of the invention which are, for clarity, described herein in the context of separate embodiments, may also be provided in combination in a single embodiment. Conversely, various features of the invention that are, for brevity, described in the context of a single embodiment, may also be provided separately or in any subcombination. Further, reference to values stated in ranges include each and every value within that range.

In one aspect, the present disclosure provides devices. The devices may include an amorphous resistance-switching layer, the layer comprising an electrically semiconducting composition; and one or more electronegative elements disposed within the electrically semiconducting composition, the layer having a cross-sectional dimension in the range of about 0.5 nm to about 60 nm; and at least one electrode in electronic communication with the amorphous layer. The amorphous resistance-switching layer may have a thickness in the range of from about 0.5 nm to about 60 nm, or more preferably from about 1 nm to about 30 nm.

As used herein, “amorphous” means a material wherein an x-ray diffraction test of the amorphous layer does not detect crystalline peak of the material. Generally, this means that there is less than about 5% by weight of the amorphous material of crystallite. Preferably, there is less than 4% by weight, or even less than 3% of weight, or even less than 2% by weight, or even less than 1% by weight of the amorphous material of crystallite. If the amorphous layer is deposited on a substrate, an x-ray diffraction test of such layer does not detect any crystalline peak other than the crystalline peak of the substrate, which may optionally include an electrode material.

As used herein, electronegative elements may be N, O, S, F, Cl, Br, or I, or more preferably, N and O, The amounts of electronegative elements are at least 1 atomic percent relative to the semiconductor. Electronegative dopants in a semiconductor may be detected using any standard means, such as x-ray fluorescence, x-ray photoemission spectroscopy (XPS), UV photoemission spectroscopy (UPS), electron-excited energy dispersive x-ray analysis (EDX), or infrared and Raman spectroscopy.

The composition of the layer may be characterized as SC[Oₓ], SC[N_{y}], or SC[OₓN_{z}]. “SC” suitably comprises the electrically semiconducting composition. X may be in the range of between about 0.01 and less than 2, y may be in the range of between about 0.01 and less than 4/3, and z may be in the range of 0.01 and less than (4−2x)/3.

SC may comprise an elemental semiconductor, a group IV compound semiconductor, a group III-V semiconductor, a group II-VI semiconductor, a group IV-VI semiconductor, a group II-V semiconductor, or any combination thereof. Suitable elemental semiconductors comprise Si, Ge, Se, Te, or any combination thereof. Suitable group IV compound semiconductors include SiC, GeC, or any combination thereof SC may additionally comprise n-type or p-type doped semiconducting compositions of the above.

SC may also comprise, e.g., PbSnTe, Ti₂SnTe₅, Ti₂GeTe₅, CuCl, Cu₂S, Bi₂Te₃, PbI₂, MoS₂, GaSe, SnS, Bi₂S₃, GaMnAs, InMnAs, CdMnTe, PbMnTe, CuInSe₂, AgGaS₂, ZnSiP₂, As₂S₃, PtSi, BiI₃, HgI₂, TiBr, AgS, FeS₂, Cu₂ZnSnS4, or any combination and n/p-doped semiconducting compositions thereof.

In some embodiments, the group III-V semiconductor has the formula AB, and wherein A comprises B, Al, Ga, or In, and wherein B comprises N, P, As, or Sb. A group II-VI semiconductor may have the formula AB, wherein A comprises Zn, Cd, or Hg, and wherein B comprises S, Se, or Te. A group IV-VI semiconductor may have the formula AB, wherein A comprises Sn or Pb, and wherein B comprises S, Se or Te. A group II-V semiconductor has the formula A₃B₂, wherein A comprises Cd or Zn, and wherein B comprises P, As, or Sb. Semiconductors may additionally comprise n-type or p-type doped compositions, e.g., n-type or p-type doped compositions of the above.

An amorphous layer may also include a metal. Suitable metals include Li, Na, K, Rb, Cs, Be, Mg, Ca, Sr, Ba, Sc, Y, Ti, Zr, Hf, V, Nb, Ta, Cr, Mo, W, Mn, Tc, Re, Fe, Ru, Os, Co, Rh, Ir, Ni, Pd, Pt, Cu, Ag, Au, Zn, Cd, B, Al, Ga, In, C, Si, Ge, Sn, Pb, La, Ce, Pr, Nd, Pm, Sm, Eu, Gd, Tb, Dy, Ho, Er, Tm, Yb, Lu, or any combination thereof.

In some embodiments, a device may include an additional layer in contact with the amorphous layer. The additional layer may have a thickness in the range of from about 0.3 nm to about 10 nm. Without being bound to any particular embodiment, the additional layer may serve as a protective layer between the amorphous layer and the environment exterior to that amorphous layer. The additional layer may be an electrically insulating layer, or dimensioned such that it does not eliminate electrical communication. The additional layer may be a material that confers scratch resistance on the device or otherwise protects the underlying amorphous layer.

The additional layer may include Li, Na, K, Rb, Cs, Be, Mg, Ca, Sr, Ba, Sc, Y, Ti, Zr, Hf, V, Nb, Ta, Cr, Mo, W, Mn, Tc, Re, Fe, Ru, Os, Co, Rh, Ir, Ni, Pd, Pt, Cu, Ag, Au, Zn, Cd, B, Al, Ga, In, C, Si, Ge, Sn, Pb, La, Ce, Pr, Nd, Pm, Sm, Eu, Gd, Tb, Dy, Ho, Er, Tm, Yb, Lu, or any combination thereof.

An additional layer may also be characterized as having the formula AOₓ, wherein A comprises Li, Na, K, Rb, Cs, Be, Mg, Ca, Sr, Ba, Sc, Y, Ti, Zr, Hf, V, Nb, Ta, Cr, Mo, W, Mn, Tc, Re, Fe, Ru, Os, Co, Rh, Ir, Ni, Pd, Pt, Cu, Ag, Au, Zn, Cd, B, Al, Ga, In, Si, Ge, Sn, Pb, La, Ce, Pr, Nd, Pm, Sm, Eu, Gd, Tb, Dy, Ho, Er, Tm, Yb, or Lu, a nitride ANₓ, wherein A comprises B, Al, Ga, In, C, Si, Ge, or Sn, or an oxynitride AOₓN_{y}, wherein A comprises B, Al, Ga, In, Si, Ge, or Sn, or any combination thereof.

The additional layer may also be characterized as an oxynitride having the formula AOₓN_{y}M_{z}, wherein A comprises B, Al, Ga, In, C, Si, Ge, Sn, or any combination thereof, and M comprises of Li, Na, K, Rb, Cs, Be, Mg, Ca, Sr, Ba, Sc, Y, Ti, Zr, Hf, V, Nb, Ta, Cr, Mo, W, Mn, Tc, Re, Fe, Ru, Os, Co, Rh, Ir, Ni, Pd, Pt, Cu, Ag, Au, Zn, Cd, Pb, La, Ce, Pr, Nd, Pm, Sm, Eu, Gd, Tb, Dy, Ho, Er, Tm, Yb, Lu, or any combination thereof. An additional layer may also include C, Si, Ge, B₂O₃, Al₂O₃, Ga₂O₃, In₂O₃, SiO₂, GeO₂, SnO₂, TiO₂, ZrO₂, HfO₂, VO₂, Nb₂O₅, Ta₂O₅, BN, AlN, Si₃N₄, Ge₃N₄, SiC, GeC or any combination thereof. The additional layer may be disposed between the amorphous resistance-switching layer and the electrode. The additional layer may also be disposed between the amorphous resistance-switching layer and a gate electrode. The additional layer may also include N, O, S, F, Cl, Br, or I. In some embodiments, the additional layer is dimensioned such that it does not eliminate electrical communication between the amorphous layer and the electrode, terminal, or other component of the device. In some embodiments, the additional layer contacts both an electrode and the amorphous layer.

In the disclosed devices, the electrically semiconducting composition may suitably include at least one of Si and Ge; Si, including n-type and p-type doped Si, is considered especially suitable. Suitable electronegative elements include O and N.

A device according to the present disclosure may be configured as a resistive memory, as a capacitive memory device, or both. A memory device according to the present disclosure may have at least two resistance states. In some embodiments, the device is a non-volatile memory device having two or more stable states. In certain embodiments, a device may be switched from an initially low resistance state to a high resistance state by a voltage. After the voltage is removed, the resistance is higher than the initial value. Optionally, the high resistance state can be subsequently switched back to the low resistance state; after the voltage is removed, the resistance is lower than the previous value. The device is thus a non-volatile resistive memory device. The device may be likewise switched between a low capacitance state and a high capacitance state, in a non-volatile manner, to provide a non-volatile capacitive memory device.

Devices according to the present disclosure may have two or more resistance states having non-volatile resistances that differ by at least 5%. The devices may also have two or more resistance states having non-volatile capacitances that differ by at least 3%, or even at least 1%.

An exemplary device may include two or more terminals, such as a source and a drain; devices may also include one or more gate electrodes. The terminals may be used to provide a voltage or current, or to switch the resistive or capacitive state, or to sense the resistive or capacitive state, or to bias or regulate the device current, voltage, charge or capacitance, as commonly practiced for electrodes in a two-terminal or multi-terminal memory, diode, or transistor. The gate electrodes may be used to provide a voltage to bias or regulate the device current, voltage, charge, or capacitance, as commonly practiced for gate electrodes in a transistor or a field effect transistor.

Also provided are methods. These disclosed methods suitably include disposing, on a substrate, a semiconducting material and one or more electronegative elements such that the semiconducting material and the one or more electronegative elements form an amorphous layer, the layer having a thickness or cross-sectional dimension in the range of from about 0.5 nm to about 60 nm.

The composition of the layer may be characterized as SC[Oₓ], SC[N_{y}], or SC[OₓN_{z}], wherein “SC” comprises the electrically semiconducting composition and wherein x is in the range of between about 0.01 and less than 2, wherein y is in the range of between about 0.01 and less than 4/3, and wherein z is in the range of between about 0.01 and less than (4−2x)/3. SC may additionally comprise n-type or p-type doped semiconducting compositions of the above.

As described elsewhere herein, the layer may further include one or more metals. Suitable metals are described elsewhere herein. Such metal may be incorporated with one or more electronegative dopants. In certain embodiment, a metal such as Hf may be incorporated with O, an electronegative element, by incorporating its oxide HfO₂, an insulator, into the amorphous layer. The composition of the layer may then be characterized as

SC[OₓHf_{x/2}], wherein SC comprises the electrically semiconducting composition and wherein x is in the range of between about 0.01 and less than 2. In another embodiment, a metal such as Al may be incorporated with N, an electronegative element, by incorporating its nitride AlN, an insulator, into the amorphous layer, The composition of the layer may then be characterized as SC[N_{y}Al_{y}], wherein SC comprises the electrically semiconducting composition and wherein y is in the range of between about 0.01 and less than 2.

The substrate may be, e.g., crystalline Si. Other crystalline materials, e.g., GaAs, InGaAs, Al₂O₃, GaN, or SiC, may be used. Amorphous substrates (e.g., glass, amorphous SiO₂, amorphous Si, amorphous GeO₂, amorphous Ge, and polymer and soft materials) may also be used. Metal elements may be incorporated into the film by co-sputtering a semiconductor target (e.g., Si) with a metal oxide target (e.g., HfO₂, AlO_{3/2}) or a metal nitride target (e.g., AlN). (In such case, the electronegative elements are incorporated at the same time.) A wide range of sputtering conditions may be used depending on the targets, gas atmosphere, layer thickness and other parameters (e.g., sputtering time, the power limit of the equipment) desired or applicable. For example, the RF power may range from 20 W to 400 W in the atmosphere of argon with a flow rate of 0.1 sccm to 30 sccm for a time from 1 minute to 30 minute.

Disposing may include, e.g., sputtering the semiconducting material in the presence of the one or more electronegative elements. The one or more electronegative elements may be present in fluid (e.g., gas) form. This may be accomplished by, e.g., sputtering silicon in the presence of a flow of oxygen gas; that is, by reactive sputtering. For example, during RF sputtering of a silicon target (RF power set at, e.g., 200 W), a small amount of oxygen or nitrogen may be injected into the atmosphere of argon in order to provide electronegative dopants. To control the composition of dopants, a flow rate of oxygen or nitrogen may be, e.g., adjusted from 0.1 sccm to 10 sccm while the flow rate of argon is fixed at 20 sccm. The foregoing conditions, materials, and setting are exemplary only and are not limiting.

In one exemplary case of co-sputtering, Si and AlO_{3/2}, the sputtering power of Si may be from, e.g., 20 W to 200 W, and the sputtering power of AlO_{3/2} is from, e.g., 50 W to 200 W. Deposition times in the range of from 1 min to 10 min are suitable. For co-sputtering Si and HfO₂, the sputtering power of Si may be from, e.g., 20 W to 200 W, and the sputtering power of HfO₂ is from, e.g., 20 W to 200 W. Using suitable appropriate deposition times, values of RF power may be from 20 W to 400 W for most targets.

In the case of reactive sputtering, fixing the flow rate of argon at 20 sccm, suitable flow rates are from 0.1 sccm to 10 sccm for both oxygen and nitrogen. Alternatively, a flow of gas mixture of argon and oxygen or a mixture of argon and nitrogen gas (with the composition of oxygen or nitrogen from 0.01% to 5%) may be used instead of separate flows of argon and pure oxygen or pure nitrogen. If a mixture of gas is injected, the flow rate may be about 0.1 sccm to 30 sccm. If pure argon is also injected, the flow rate of mixture gas may be comparable with, or smaller or larger than that of argon; e.g., if argon has a rate of 5 sccm, a mixture gas may have the rate from 1 sccm to 20 sccm. It should be understood that the foregoing values are all exemplary only and are not exclusive.

A semiconducting material may include an elemental semiconductor, a group IV compound semiconductor, a group III-V semiconductor, a group II-VI semiconductor, a group IV-VI semiconductor, a group II-V semiconductor, or any combination thereof. It may additionally comprise n-type or p-type doped semiconducting compositions of the above.

In some embodiments, disposing comprises sputtering the semiconducting material and also sputtering a second composition that comprises one or more electronegative elements. The second composition may be, e.g., an oxide AOₓ, wherein A comprises Li, Na, K, Rb, Cs, Be, Mg, Ca, Sr, Ba, Sc, Y, Ti, Zr, Hf, V, Nb, Ta, Cr, Mo, W, Mn, Tc, Re, Fe, Ru, Os, Co, Rh, Ir, Ni, Pd, Pt, Cu, Ag, Au, Zn, Cd, B, Al, Ga, In, Si, Ge, Sn, Pb, La, Ce, Pr, Nd, Pm, Sm, Eu, Gd, Tb, Dy, Ho, Er, Tm, Yb, Lu, a nitride ANₓ, wherein A comprises B, Al, Ga, In, C, Si, Ge, or Sn, or an oxynitride AOₓN_{y}, wherein A comprises B, Al, Ga, In, Si, Ge, or Sn.

The second composition may be an oxynitride having the formula AOₓN_{y}M_{z}, wherein A comprises B, Al, Ga, In, C, Si, Ge, Sn, or any combination thereof, and M comprises of Li, Na, K, Rb, Cs, Be, Mg, Ca, Sr, Ba, Sc, Y, Ti, Zr, Hf, V, Nb, Ta, Cr, Mo, W, Mn, Tc, Re, Fe, Ru, Os, Co, Rh, Ir, Ni, Pd, Pt, Cu, Ag, Au, Zn, Cd, Pb, La, Ce, Pr, Nd, Pm, Sm, Eu, Gd, Tb, Dy, Ho, Er, Tm, Yb, Lu, or any combination thereof.

As described elsewhere herein, an electronegative element may be N, O, S, F, Cl, Br, or I. O and N are considered especially suitable electronegative elements.

Additionally provided are methods. These methods include placing a layer of semiconducting material into contact with a second layer of material that comprises an electronegative element; and effecting disposition of at least some of the electronegative element within the layer of semiconducting material, forming an amorphous layer. These methods may include techniques that promote material mixing between the semiconducting and second layers, such as thermal annealing, ion-bombardment-induced mixing, plasma treatment, and combinations thereof.

The composition of the amorphous layer (as described elsewhere herein) may be characterized as SC[Oₓ], SC[N_{y}], or SC[OₓN_{z}], wherein SC comprises the electrically semiconducting composition and wherein x is in the range of between about 0.01 and less than 2, wherein y is in the range of between about 0.01 and less than 4/3, and wherein z is in the range of between about 0.01 and less than (4−2x)/3. The amorphous layer may also include a metal; suitable metals are described elsewhere herein.

Further disclosed methods include contacting an electrode that comprises an electronegative element with a layer of semiconducting material; and effecting disposition of at least some of the electronegative element within the layer of semiconducting material, forming an amorphous layer.

The methods may include thermal annealing, ion-bombardment-induced mixing, plasma treatment, or any combination thereof; techniques that promote material mixing at the interface between the electrode and the semiconducting material are suitable.

As described elsewhere herein, the composition of the amorphous layer may be characterized as SC[Oₓ], SC[N_{y}], or SC[OₓN_{z}], wherein SC comprises the electrically semiconducting composition and wherein x is in the range of between about 0.01 and less than 2, wherein y is in the range of between about 0.01 and less than 4/3, and wherein z is in the range between about 0.01 and less than (4−2x)/3. The amorphous layer may include a metal. Suitable SC examples and suitable metals are described elsewhere herein.

Suitable semiconducting materials are described elsewhere herein; such materials may include an elemental semiconductor, a group IV compound semiconductor, a group III-V semiconductor, a group II-VI semiconductor, a group IV-VI semiconductor, a group II-V semiconductor, or any combination thereof.

### ILLUSTRATIVE EXAMPLES

Example (1) An example of a resistance-switching memory device is described using thermal oxide coated single crystal n-type or p-type silicon with 100 or 111 orientations as the substrate, polycrystalline Mo or Ti as the bottom electrode, Pt as the top electrode, and doped silicon (SiOₓ or SiNₓ) or insulator-mixing silicon (Si-I, I stands for an insulator selected from the group of SiN_{4/3}, SiO₂, AlN, AlO_{3/2}, HfO₂) as the amorphous layer. The various materials above do not share a common structure, other than being amorphous. Indeed, crystalline Si, SiN_{4/3}, SiO₂, AlN, AlO_{3/2}, HfO₂ all have distinct and different crystal structures. The amorphous mixture layers can be deposited on unheated substrates; on the same unheated substrate, the deposited electrodes are usually polycrystalline. The test cells in current example device had a diameter of ˜100 microns (“μm”).

The Pt top electrode in (1) provides scratch resistance and thus convenient for laboratory electrical testing using a test probe, but other common electrodes can also be used. The Mo or Ti bottom electrode in (1) provides a flat sputtered interface thus convenient for subsequent amorphous layer deposition, but other common electrodes can also be used. Common electrodes include but are not limited to Mo, W, Cu, Ta, Al, Ag, Au, Cr, Ni, Pd, NbN, TaN, TiN, ZrN, HfN, PtSi₂, TiSi₂, CoSi₂, NiSi₂, NbSi₂, TaSi₂, MoSi₂ and WSi₂.

The bottom electrode was deposited by DC-sputtering. The top electrode was also deposited by DC-sputtering, through a shadow mask. Film thickness, orientation and crystallinity were determined by a theta-2 theta diffractometer using a Cu Kα source. The surface morphology was observed by atomic force microscopy.

Reactive RF-sputtering was used to deposit the amorphous SiOₓ or SiNₓ layer. RF-cosputtering was used to deposit the amorphous Si—I (as used herein: Si—I stands for a binary mixture between Si and I, wherein I═SiN_{4/3}, SiO₂, AlN, AlO_{3/2}, HfO₂) layer using a silicon target and an insulator (I) target simultaneously. These semiconductor and insulator targets can also be used—if desired—to sputter the additional inserted layer of a semiconductor or an insulator, between the amorphous SiOₓ, SiNₓ, and Si—I. This additionally inserted layer of semiconductor or insulators may be deposited or introduced by, e.g., atomic layer deposition (ALD). Electrical properties were measured using several electrical meters on a probe station. The resistance switching film was verified to be amorphous using a theta-2 theta diffractometer.

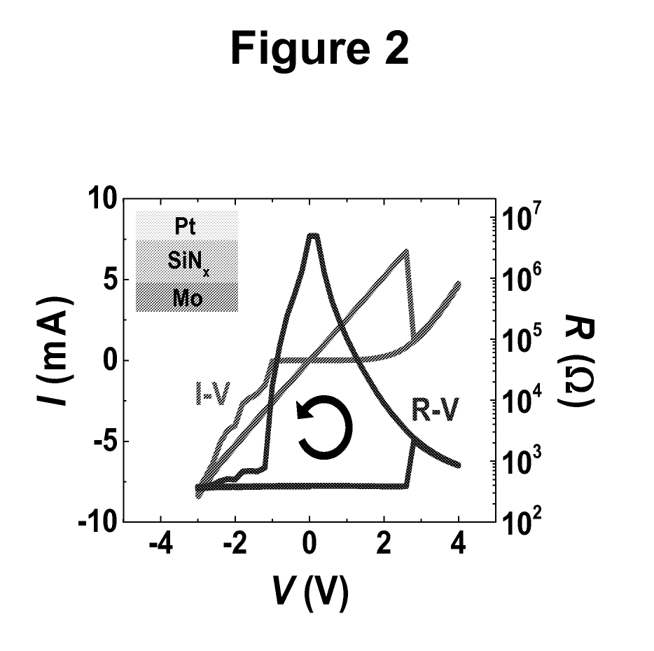

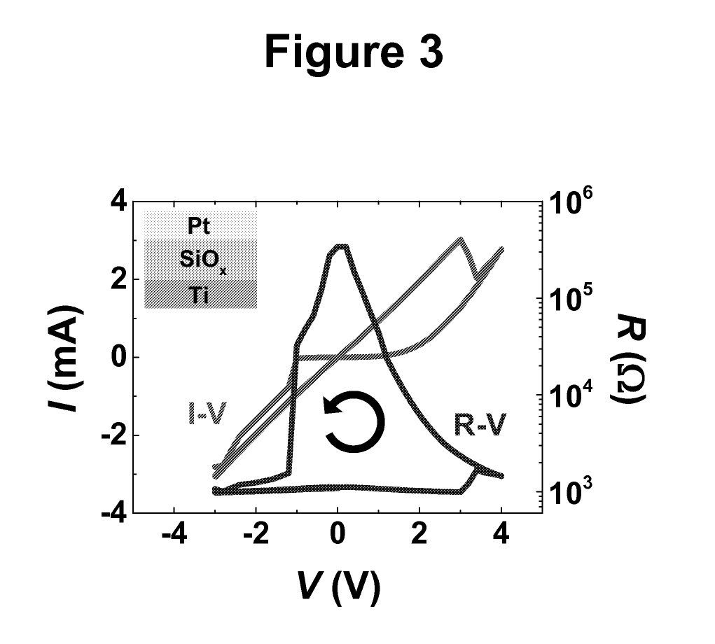

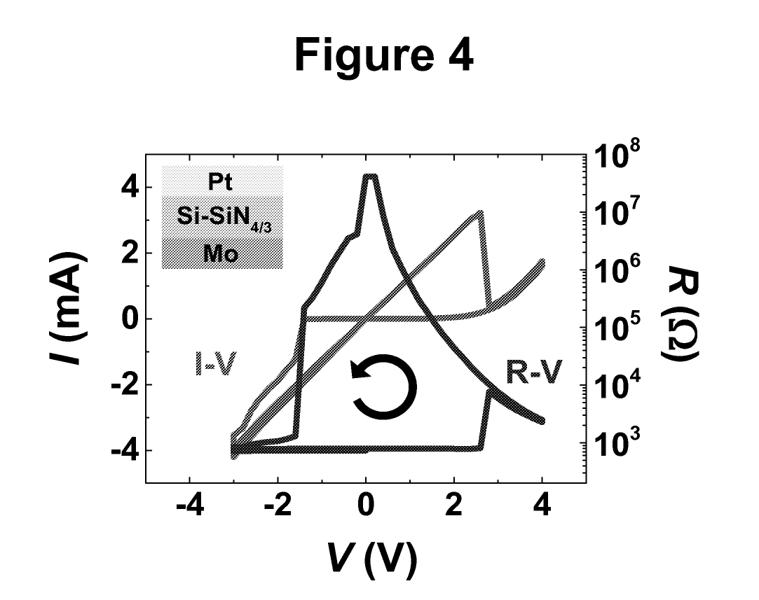

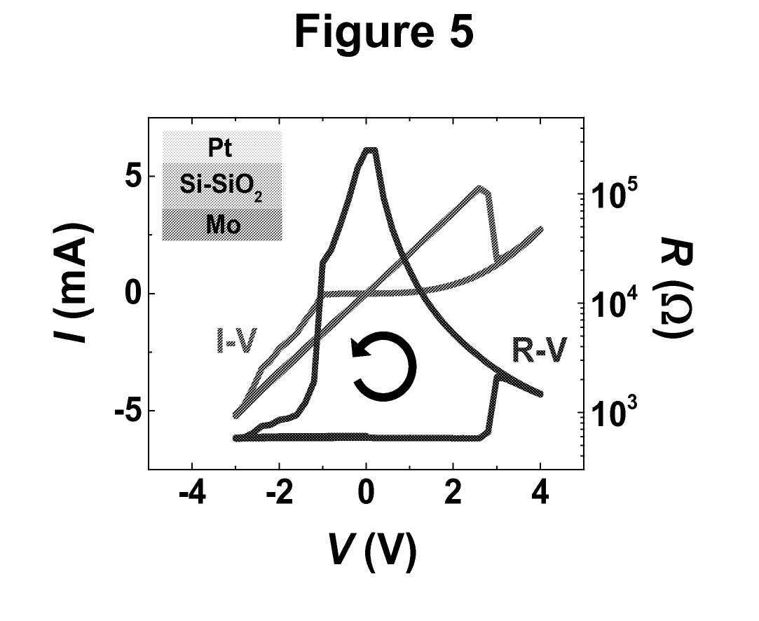

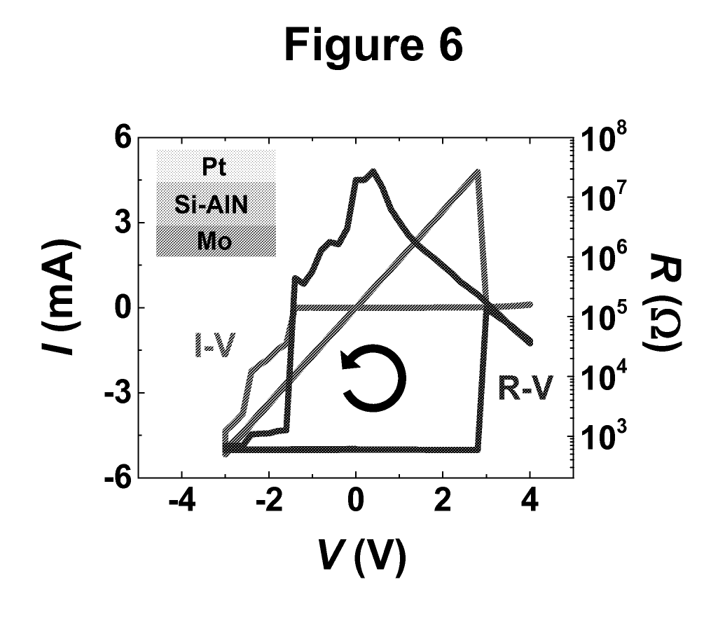

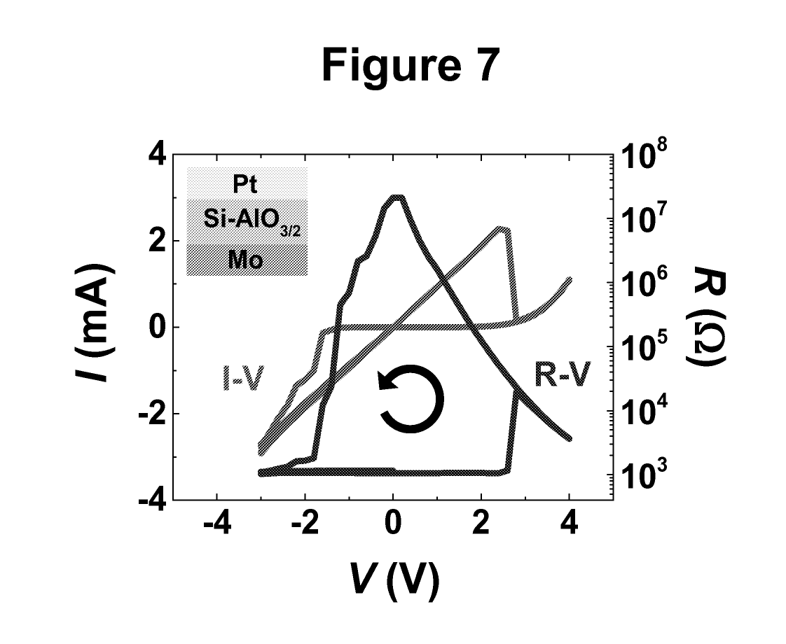

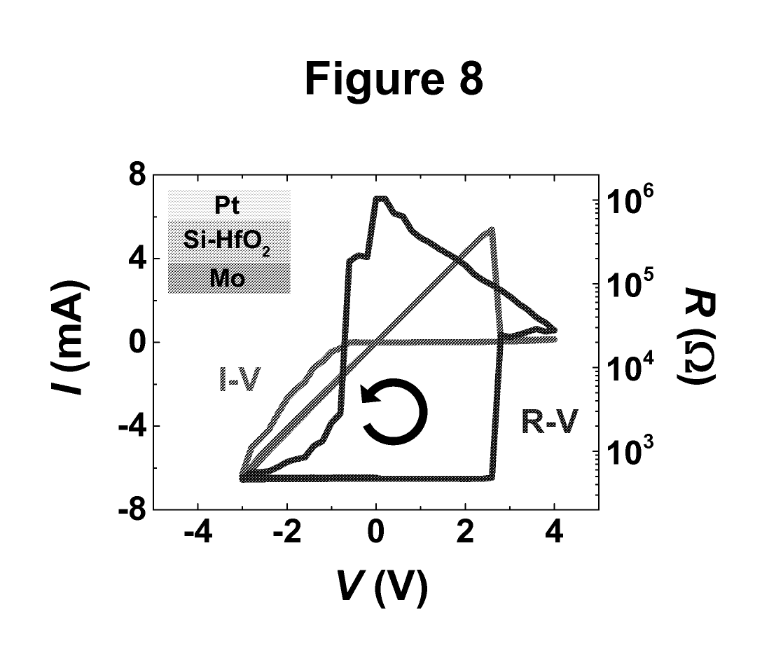

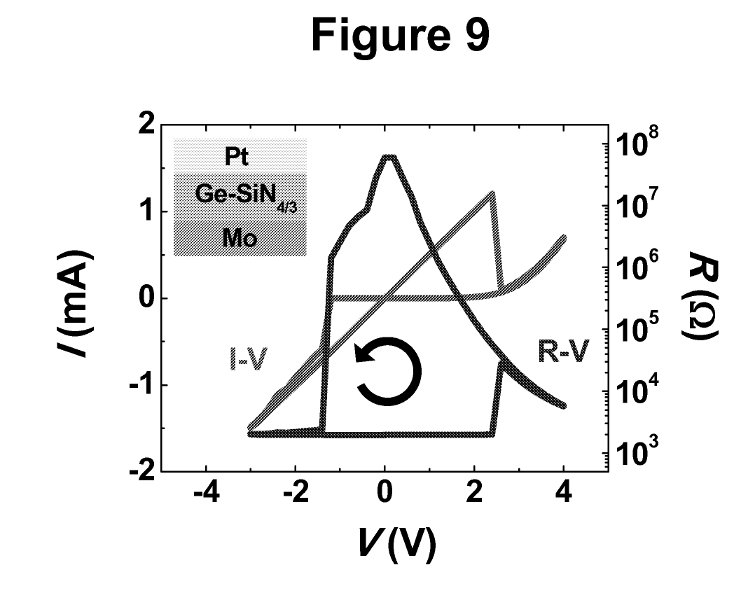

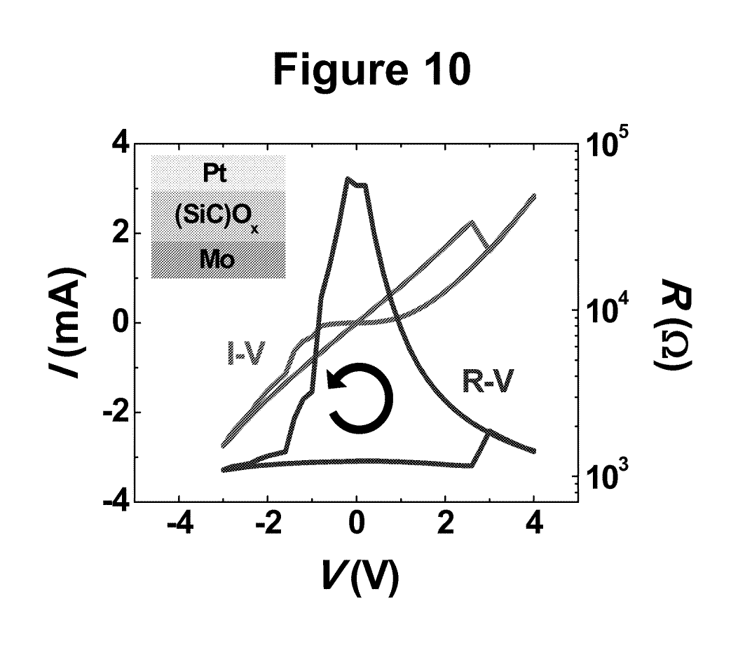

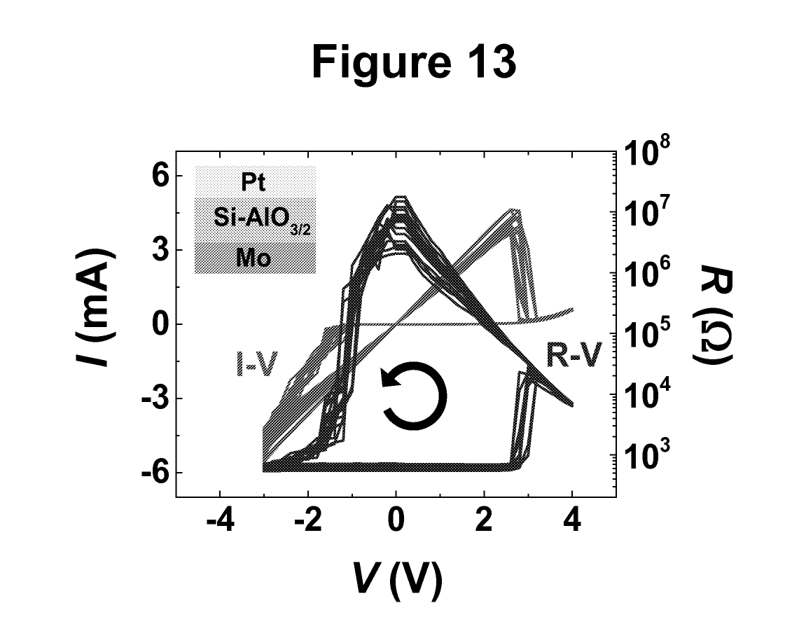

The above heterostructure thin film devices show excellent resistance-switching between an initial low-resistance and a set high resistance, as shown by the current-voltage (I-V) and the resistance-voltage (R-V) curves in FIGS. 2-12. The on-off ratio of the resistance in the test devices typically exceeds 100:1. The device was tested repeatedly and showed little change in memory of either high or low resistance, as evidenced by the 20 overlapping R-V loops shown in FIG. 13.

Current-voltage (I-V) and resistance-voltage (R-V) curves were measured in continuous voltage-sweep modes. As used in the following tests, positive bias is the one causing a current to flow from the top electrode to the bottom electrode. A typical room temperature I-V and R-V curves of a device with an amorphous resistance-switching layer of SiNₓ and Pt/Mo top/bottom electrodes as shown in FIG. 2 has a switching voltage of 2.5 V for low resistance to high resistance, and a switching voltage of −1 V for high resistance to low resistance. The I-V and R-V curves were recorded in the voltage-control mode. The resistance defined as the ratio of V/I is plotted along with a schematic circle indicating the rotational direction of the R-V hysteresis. The device shows a low initial resistance 380Ω and this low resistance state is stable under a negative bias.

Under a positive bias, the low resistance state is still stable below 2.5 V, but the resistance suddenly increases to a larger value, 2100Ω when the bias exceeded 2.5 V. The high resistance state is highly non-linear with a resistance value that increases with decreasing voltage. The zero-voltage resistance is typically higher than 100 kΩ and this high resistance state is maintained at zero voltage indicating the memory is non-volatile. The resistance ratio (i.e., the on-off ratio) of the high resistance state to the low resistance state thus exceeds 260 in the above case. The high resistance state is still maintained until a negative bias of about −1.0 to −1.5 V is applied, which switches the resistance back to the low resistance state.

The device also allowed a read voltage between −0.5 V and +1 V without disturbing the high and low resistance states.

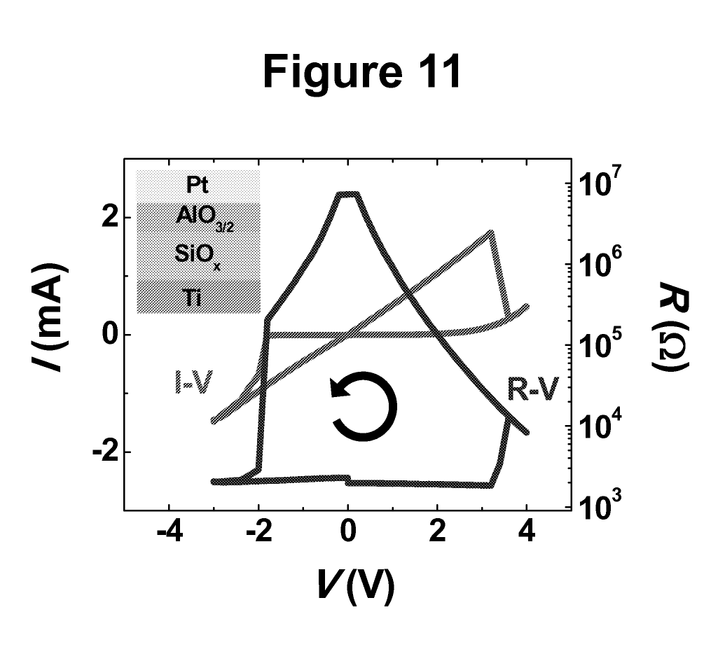

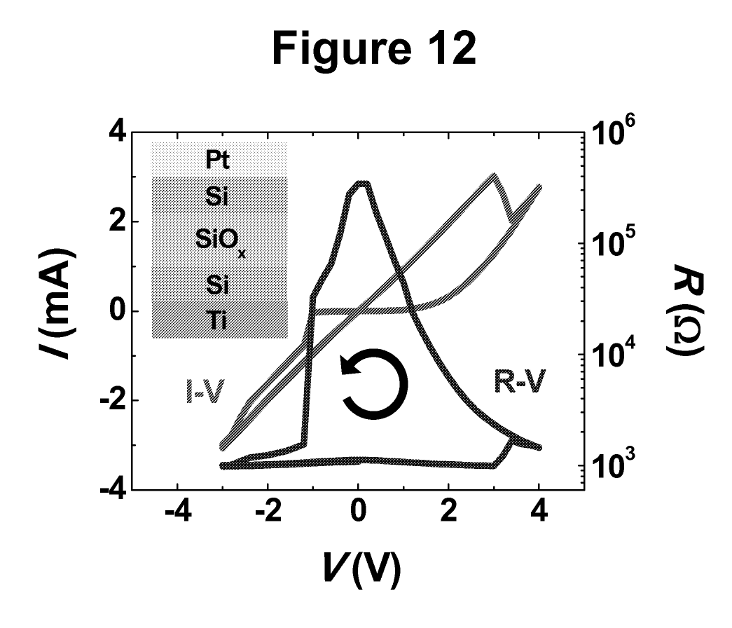

Adding one or more layers of amorphous insulators or semiconductors between the resistance-switching layer and electrodes enhances device performance without degrading the switchability. Examples are shown in FIGS. 11-12. Their R-V curve shows similar switching characteristics to those in FIGS. 2-10. In FIG. 11, an AlO_{3/2}layer was deposited using ALD in order to protect the resistance-switching layer and to increase the on-off ratio after the deposition of SiOₓ (the resistance-switching layer) by reactive sputtering. The device structure in FIG. 12 has two inserted layers of amorphous silicon, a semiconducting composition, above and below SiOₓ (the resistance-switching layer), preventing electrodes from oxidation and improving the performance of resistance switching.

FIG. 11 provides an example to show that the amorphous mixture layer need not be in direct contact with the electrode. (In this instance, Al₂O₃ is an insulator.) It also provides an example to lead to three terminal devices which typically have an insulator between the device layer and an electrode, the insulator is commonly referred to as gate oxide.

Another embodiment illustrated by FIG. 11 is that the nominally insulating film, such as Al₂O₃ in this case, may actually be conducting when it is very thin. When the film is sufficiently thin, it has sufficient conductivity to allow the amorphous mixture layer to be in electrical communication with the top electrode despite the existence of an intervening layer. In practice, the insertion of this nominally insulating film allows the use of amorphous mixture layer that is thinner than usual, so thin that it is always conducting and not switchable unless it is covered by a thin Al₂O₃ film.

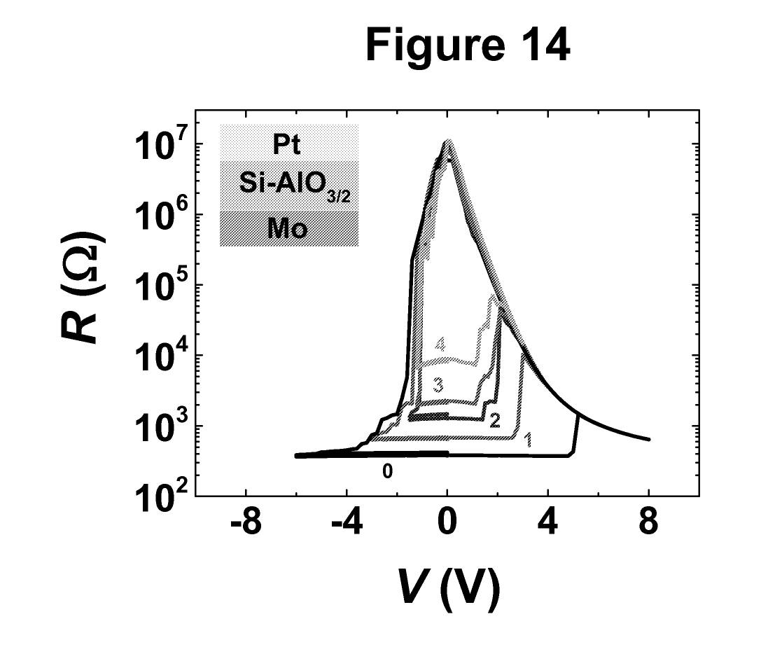

Switchable devices exhibit multilevel resistance states that are suitable for multi-bit data storage within a single cell. One example is shown in FIG. 14. Five distinct resistance states achieved by varying the stress voltage are labeled as “0”, “1”, “2”, “3” and “4” in FIG. 14. Such multi-bit cells can increase the storage density of nonvolatile memory.

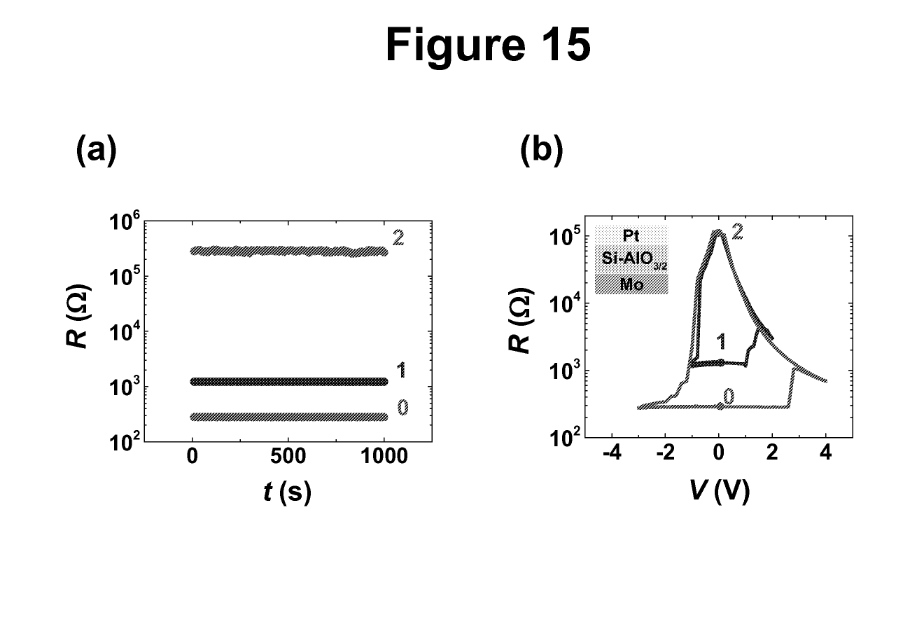

The resistance states can be kept in a non-volatile manner as verified by certain retention experiments. The devices stored in air for several months experience no memory lapse. Generally, there is no need for an electrical source to maintain the resistance states. One example is shown in FIG. 15. Data retention of three resistance states (“0”, “1” and “2”) from FIG. 15(b) was tested using consecutive read operations at 0.1 V with certain rate (one read per second). As shown in FIG. 15(a), no obvious degradations were observed in 1000 s, indicating each state is stable and non-volatile for data storage.

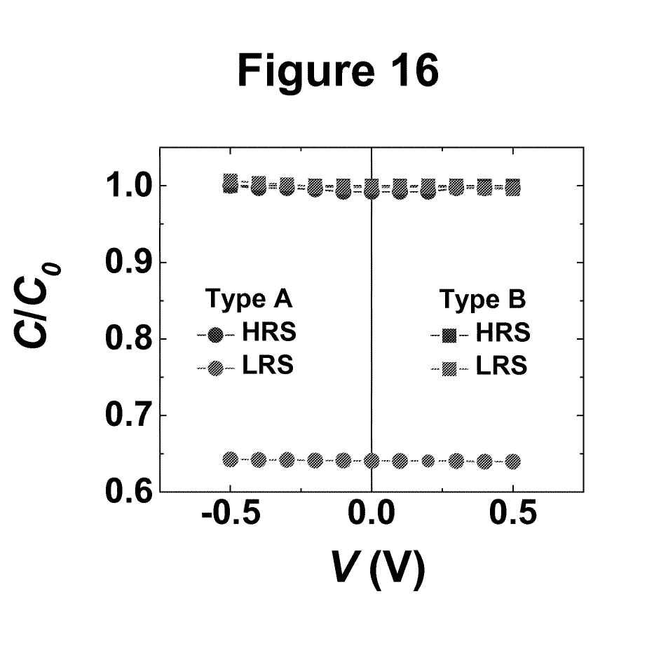

There are two distinct types of switching materials in switchable devices as revealed by the capacitance-voltage (C-V) measurement for the high resistance state (HRS) and the low resistance state (LRS) shown in FIG. 16. At a fixed bias, the real part and imaginary part of the device impedance under swept frequencies were measured to generate a Cole-Cole plot. Then, capacitance was obtained by fitting the data with an appropriate equivalent circuit. (One set of resistor and capacitor, connected in parallel, with another set of serial resistor and serial inductor connected to this parallel circuit in this case.) The capacitance of the HRS can also be measured using a standard capacitor meter.

In what one may term a Type A sample, the capacitance of the low resistance state (LRS) is about 35% less than that of the high resistance state (HRS), while in what one may term a Type B sample, these two capacitances are almost identical. These results are highly reproducible and whether a sample is Type A or Type B depends on the composition. Without being bound to any particular theory, broadly speaking the Type A samples have a lower content of electronegative dopants or insulators than the Type B samples. At the intermediate composition, the distinction between the two types disappears, and Type A evolves into Type B as the content of electronegative dopants or insulators increases. The distinctly different capacitances of the two states, which are maintained at zero voltage, provide another method to store memory.

FIG. 16 and the distinction between Type A and Type B provide an important way to distinguish the invention and the more common resistance switching material. The more common material is an insulator which breaks down to form filaments. This is also called filamentary resistance memory material and it is the Type B above. That is, a standard insulator can often be made into a filamentary resistance memory material (Type B) if its thin film is first formed (i.e., it breaks down to form filaments inside). The invention of Type A material is totally unexpected, and it can be distinguished with the more common Type B material using the capacitance measurement. The silicon and other semiconductor materials provide a platform to include both Type A and Type B materials: when the silicon is more lightly doped with electronegative dopants, it becomes more conducting and a switching transition of resistance happens under a voltage. This is the Type A material.

When the silicon is heavily doped with electronegative dopants, it becomes entirely insulating and a switching transition of resistance happens if the film is first “formed”, to produce filaments, then its resistance can be switched by a voltage. This is the Type B material.

A standard insulator can also be made into a nanometallic resistance memory material (of Type A, according to the capacitance measurement and the lack of need for “forming”) if a metal is dispersed into the insulating film. It is thus clear that the present disclosure, which modifies a semiconductor (such as silicon) into a new device material, differs from exiting effort, which modifies an insulator into a new device material.

Exemplary switchable devices were fabricated using a broad range of parameters, which are the amorphous mixture layer thickness (δ) and the oxygen/nitrogen to silicon atomic ratio defined as x in the formula Si[Oₓ] or Si[N_{y}] of the amorphous mixture layer. The layer may further comprise a metal, such as Al.

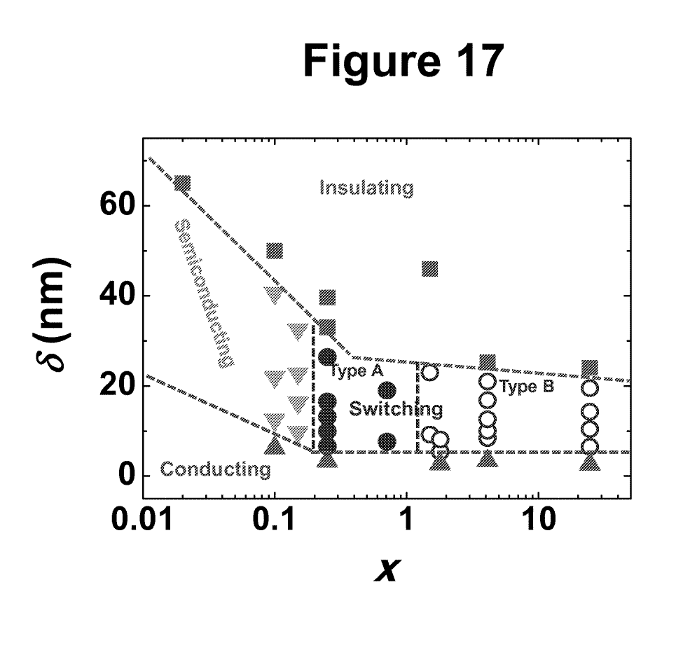

A further example is shown in FIG. 17 for devices made of an amorphous Si—AlO_{3/2} binary mixture layer. FIG. 17 depicts an illustrative map of thickness (δ)-oxygen composition combinations (x as in SC[Oₓ], where SC is the semiconducting composition) for rendering switching device using amorphous Si—AlO_{3/2} mixture layer. Si is the semiconducting composition, and AlO_{3/2} is the insulating composition that supplies electronegative dopant O. Films of large thickness are insulting, films of thin thickness are conducting. Films of intermediate thickness are either semiconducting or switching depending on x. Among the switching films, type A switching occurs at smaller x, and type B at larger x.

### Exemplary Synthesis/Deposition

Sputtering is one convenient (but non-limiting) method to make suitable films. A single target of Si (or n/p-type doped Si) can be used, with concomitant or post-sputtering introduction of O and N in a variety of forms. Similarly, a silicon target and an oxide target (such as SiO₂, Al₂O₃, and HfO₂) or a nitride target (such as Si₃N₄ or MN) can be used to allow co-sputtering to introduce O or N. (The species of Si, Al, and Hf introduced by this process may not necessarily be in metal form; they may be in cation form, bonded to O or N.) However, other methods can also be used, and such methods include, without limitation, direct-current sputtering, radio-frequency sputtering, cold-substrate or heated-substrate sputtering, ion/laser/plasma-assisted sputtering, pulse laser deposition, physical vapor deposition, atomic layer deposition, co-evaporation techniques, wet chemical methods, and any other method, present or future for constructing an amorphous layer. The electronegative dopants can also be introduced into the amorphous layer by ion implantation, diffusion, or any other method of introduction.

In addition, substitution and/or displacement reactions may be used to fabricate such amorphous films with high precision. For example, a silicon film may be first deposited, followed by the deposition of a transition metal (M) oxide film (e.g., MO) such as a NiO film. The bilayer, after annealing, will evolve into a Ni film over a Si:O film, wherein Si:O is a binary mixture composition of Si and O, since thermodynamically O prefers to form a solution with Si than with Ni. (In this case, Si is oxidized into Si:O and NiO is reduced to Ni.) A similar reaction can be contemplated involving a transition metal (M) nitride (such as MN) on a Si film, which after displacement reaction forms a bilayer structure comprising of an M layer above a Si:N layer, wherein Si:N is a binary mixture composition of Si and N. In the above examples, by adjusting the thickness of the MO or AlN layer, other structures can be fabricated, such as having a very thin nominally insulating film above an amorphous mixture film, or a single-layer film of Si:(M,O) or Si:(M,N). Other possibilities also exist and they should be obvious to those skilled in the art.

### Mechanisms of Conduction and Switching

Without being bound by any particular theory, the following is one explanation of the origins of low resistance conduction and its two-way switching to the high resistance state.

Amorphous silicon is a semiconductor with a band gap of 1.7 eV, with the conduction band composed of Si sp³ antibonding states, and the valence band composed of Si sp³ bonding states. It is an n-type semiconductor due to the states of dangling bonds that lie at 0.7 eV below the conduction band. These states set the value of the Fermi level, i.e., the Fermi level is effectively pinned at 0.7 eV below the conduction band edge. The addition of electronegative dopants, such as O and N, forms Si—O—Si, i.e., O—Si₂ bonds, or N—Si₃ bonds, which have energies much lower than the original valence band of the Si sp³ bonding states. Therefore, these states, which have a strong character of O2p (or N2p) are fully occupied and form the new valence band in the doped material. As such, they do not contribute to conduction.

Meanwhile, the energy of the states at 0.7 eV below the conduction band of Si sp³ antibonding states remains little changed but its population initially increases due to O doping. The additional population may be considered to come from dopant-introduced impurity states which effectively form a new conduction band when their population becomes high. As its level coincides with the Fermi level, it explains the origin of good conductivity of the low resistance states in thin films. However, because of the random nature of the amorphous structure, conduction preferably occurs on certain sites which may be regarded as conducting channels; such channels extend a certain length, and they coexisit with sites that are non-conducting or conducting only over a very short length. Therefore, over a sufficiently long distance, random fields will prevail and long range conduction is not possible. This may underlie FIG. 17, which figure shows sufficiently thin films of mixed amorphous layers are conductors, while thick films are insulators.

The switching to the high resistance state in films of intermediate thickness of an initial low resistance may be due to the injection of electrons which are trapped at some impurity states not spatially connected to the impurity-state-associated conducting channels. As a result, the isolated trapped charge forms negatively charged centers that cause electrostatic repulsion to itinerary electrons on the conducting channel, hampering electron's movement. This is the origin of switching to the high resistance states. Conversely, if the trapped charge is released by a reverse voltage bias, then the electrostatic repulsion is removed and the high resistance state returns to the low resistance states. This is the origin of switching to the low resistance states. This mechanism explains switching in the discovered materials.

The above conduction and switching mechanisms rely upon an amorphous semiconducting composition doped with oxygen (or other electronegative elements), in electrical contact with at least one electrode for providing and removing electrons. Obviously, the presence of one or more additional conducting or insulating phases, including filler phases and voids, does not fundamentally affect the above mechanism and the operation of the device as long as it does not completely block or short-circuit the electron passage of the former composition. Therefore, any composition including the presence of one or more additional conducting or insulating phases, including filler phases and voids, is also contemplated in this invention, and it should be obvious to those skilled in the art. Moreover, when the dopant (such as oxygen) concentration is too high, the Si—O—Si—O network is continuous and the conducting islands of Si with conducting impurity bands are isolated. In such a case, the electrical property is governed by the Si—O—Si—O network, which is amorphous SiO₂, and it is an insulator. Therefore, at high dopant concentrations, conductivity is lost, and an insulator forms. As described elsewhere herein, thin films of this insulator can form filaments when it is under a large voltage, which causes dielectric breakdown. The latter is the so-called forming process and the resultant resistance memory relies on the breakdown paths: the so-called filaments. In this way, resistance switching at low electronegative dopant concentrations (Type A) and at high electronegative dopant concentrations (Type B), as shown in FIG. 17, can be distinguished. Lastly, it should be understood that a semiconducting composition used in the disclosed technology may be a doped semiconductor of n-type or p-type.

1. A device, comprising:
an amorphous resistance-switching layer comprising:
an electrically semiconducting composition; and
one or more electronegative elements disposed within the electrically semiconducting composition,
the layer having a cross-sectional dimension in the range of about 0.5 nm to about 60 nm; and
at least one electrode in electronic communication with the amorphous resistance-switching layer.

2. The device of claim 1, wherein the amorphous resistance-switching layer has a thickness in the range of from about 1 nm to about 30 nm.

3. The device of claim 1, wherein the composition of the layer is characterized as SC[Oₓ], SC[N_{y}], or SC[OₓN_{z}], wherein SC comprises the electrically semiconducting composition and wherein x is in the range of between about 0.01 and less than 2, wherein y is in the range of between about 0.01 and less than 4/3, and wherein z is in the range of 0.01 and less than (4−2x)/3.

4. The device of claim 3, wherein SC comprises an elemental semiconductor, a group IV compound semiconductor, a group III-V semiconductor, a group II-VI semiconductor, a group IV-VI semiconductor, a group II-V semiconductor, or any combination thereof.

5. The device of claim 4, wherein the elemental semiconductor comprises Si, Ge, Se, Te, or any combination thereof.

6. The device of claim 4, wherein the group IV compound semiconductor comprises SiC, GeC, or any combination thereof.

7. The device of claim 3, wherein SC comprises PbSnTe, Ti₂SnTe₅, Ti₂GeTe₅, CuCl, Cu₂S, Bi₂Te₃, PbI₂, MoS₂, GaSe, SnS, Bi₂S₃, GaMnAs, InMnAs, CdMnTe, PbMnTe, CuInSe₂, AgGaS₂, ZnSiP₂, AsS₃, PtSi, BiI₃, HgI₂, TiBr, AgS, FeS₂, Cu₂ZnSnS₄, or any combination thereof.

8. The device of claim 4, wherein the group III-V semiconductor has the formula AB and wherein in A comprises B, Al, Ga, or In, and wherein B comprises N, P, As, or Sb.

9. The device of claim 4, wherein the group II-VI semiconductor has the formula AB, wherein A comprises Zn, Cd, or Hg, and wherein B comprises S, Se, or Te.

10. The device of claim 4, wherein the group IV-VI semiconductor has the formula AB, wherein A comprises Sn or Pb, and wherein B comprises S, Se or Te.

11. The device of claim 4, wherein the group II-V semiconductor has the formula A₃B₂, wherein A comprises Cd or Zn, and wherein B comprises P, As, or Sb.

12. The device of claim 1, wherein the amorphous resistance-switching layer further comprises a metal.

13. The device of claim 12, wherein the metal comprises Li, Na, K, Rb, Cs, Be, Mg, Ca, Sr, Ba, Sc, Y, Ti, Zr, Hf, V, Nb, Ta, Cr, Mo, W, Mn, Tc, Re, Fe, Ru, Os, Co, Rh, Ir, Ni, Pd, Pt, Cu, Ag, Au, Zn, Cd, B, Al, Ga, In, C, Si, Ge, Sn, Pb, La, Ce, Pr, Nd, Pm, Sm, Eu, Gd, Tb, Dy, Ho, Er, Tm, Yb, Lu, or any combination thereof.

14. The device of claim 1, further comprising an additional layer in contact with the amorphous resistance-switching layer.

15. The device of claim 14, wherein the additional layer has a cross-sectional dimension in the range of from about 0.3 nm to about 10 nm.

16. The device of claim 14, wherein the additional layer comprises Li, Na, K, Rb, Cs, Be, Mg, Ca, Sr, Ba, Sc, Y, Ti, Zr, Hf, V, Nb, Ta, Cr, Mo, W, Mn, Tc, Re, Fe, Ru, Os, Co, Rh, Ir, Ni, Pd, Pt, Cu, Ag, Au, Zn, Cd, B, Al, Ga, In, C, Si, Ge, Sn, Pb, La, Ce, Pr, Nd, Pm, Sm, Eu, Gd, Tb, Dy, Ho, Er, Tm, Yb, Lu, or any combination thereof.

17. The device of claim 14, wherein the additional layer comprises AOₓ, wherein A comprises Li, Na, K, Rb, Cs, Be, Mg, Ca, Sr, Ba, Sc, Y, Ti, Zr, Hf, V, Nb, Ta, Cr, Mo, W, Mn, Tc, Re, Fe, Ru, Os, Co, Rh, Ir, Ni, Pd, Pt, Cu, Ag, Au, Zn, Cd, B, Al, Ga, In, Si, Ge, Sn, Pb, La, Ce, Pr, Nd, Pm, Sm, Eu, Gd, Tb, Dy, Ho, Er, Tm, Yb, Lu, a nitride ANₓ, wherein A comprises B, Al, Ga, In, C, Si, Ge, or Sn, or an oxynitride AOₓN_{y}, wherein A comprises B, Al, Ga, In, Si, Ge, or Sn. or any combination thereof.

18. The device of claim 14, wherein the additional layer comprises an oxynitride AOₓN_{y}M_{z}, wherein A comprises B, Al, Ga, In, C, Si, Ge, Sn, or any combination thereof, and M comprises of Li, Na, K, Rb, Cs, Be, Mg, Ca, Sr, Ba, Sc, Y, Ti, Zr, Hf, V, Nb, Ta, Cr, Mo, W, Mn, Tc, Re, Fe, Ru, Os, Co, Rh, Ir, Ni, Pd, Pt, Cu, Ag, Au, Zn, Cd, Pb, La, Ce, Pr, Nd, Pm, Sm, Eu, Gd, Tb, Dy, Ho, Er, Tm, Yb, Lu, or any combination thereof.

19. The device of claim 14, wherein the additional layer comprises C, Si, Ge, B₂O₃, Al₂O₃, Ga₂O₃, In₂O₃, Sc₂O₃, Y₂O₃, La₂O₃, SiO₂, GeO₂, SnO₂, TiO₂, ZrO₂, HfO₂, VO₂, Nb₂O₅, Ta₂O₅, BN, AlN, Si₃N₄, Ge₃N₄, SiC, GeC or any combination thereof.

20. The device of claim 1, wherein the electrically semiconducting composition comprises at least one of Si and Ge.

21. The of claim 1, wherein the one or more electronegative elements comprise O and N.

22. The resistive device of claim 1, wherein the electrically semiconducting composition comprises Si.

23. The device of claim 1 wherein the device is configured as a resistive memory device, as a capacitive memory device, or both.

24. The device of claim 23, wherein the resistive or capacitive memory device is a memory device having at least two resistance states.

25. The memory device of claim 23, wherein the device is characterized as being a non-volatile memory device having two or more stable states.

26. The memory device of claim 23, wherein the device has two resistance states having non-volatile resistances that differ by at least 5%.

27. The memory device of claim 23, wherein the device has two resistance states having non-volatile capacitances that differ by at least 3%.

28. The device of claim 14, wherein the additional layer is disposed between the amorphous resistance-switching layer and the electrode.

29. The device of claim 14, wherein the additional layer is disposed between the amorphous resistance-switching layer and a gate electrode.

30. The device of claim 14, wherein the additional layer comprises N, O, S, F, Cl, Br, or I.

31. The device of claim 1, wherein the device comprises two or more terminals.

32. The device of claim 1, wherein the device comprises one or more gate electrodes.

33. A method, comprising:
disposing, on a substrate, a semiconducting material and one or more electronegative elements such that the semiconducting material and the one or more electronegative elements form an amorphous layer,
the layer having a cross-sectional dimension in the range of from about 0.5 nm to about 60 nm.

34. The method of claim 33, wherein the composition of the layer is characterized as SC[Oₓ], SC[N_{y}], or SC[OₓN_{z}], wherein SC comprises a electrically semiconducting composition and wherein x is in the range of between about 0.01 and less than 2, wherein y is in the range of between about 0.01 and less than 4/3, and wherein z is in the range of between about 0.01 and less than (4−2x)/3.

35. The method of claim 33, wherein the layer further comprises a metal.

36. The method of claim 33, wherein the substrate comprises crystalline Si.

37. The method of claim 33, wherein the disposing comprises sputtering the semiconducting material in the presence of the one or more electronegative elements.

38. The method of claim 33, wherein the semiconducting material comprises an elemental semiconductor, a group IV compound semiconductor, a group III-V semiconductor, a group II-VI semiconductor, a group IV-VI semiconductor, a group II-V semiconductor, or any combination thereof.

39. The method of claim 33, wherein the one or more electronegative elements is present in fluid or gas form.

40. The method of claim 33, wherein the disposing comprises co-sputtering the semiconducting material and a second composition that comprises one or more electronegative elements.

41. The method of claim 40, wherein the second composition is an oxide AOₓ, wherein A comprises Li, Na, K, Rb, Cs, Be, Mg, Ca, Sr, Ba, Sc, Y, Ti, Zr, Hf, V, Nb, Ta, Cr, Mo, W, Mn, Tc, Re, Fe, Ru, Os, Co, Rh, Ir, Ni, Pd, Pt, Cu, Ag, Au, Zn, Cd, B, Al, Ga, In, Si, Ge, Sn, Pb, La, Ce, Pr, Nd, Pm, Sm, Eu, Gd, Tb, Dy, Ho, Er, Tm, Yb, Lu, a nitride ANₓ, wherein A comprises B, Al, Ga, In, C, Si, Ge, or Sn, or an oxynitride AOₓN_{y}, wherein A comprises B, Al, Ga, In, Si, Ge, or Sn.

42. The method of claim 40, wherein the second composition is an oxynitride AOₓN_{y}M_{z}, wherein A comprises B, Al, Ga, In, C, Si, Ge, Sn, or any combination thereof, and M comprises of Li, Na, K, Rb, Cs, Be, Mg, Ca, Sr, Ba, Sc, Y, Ti, Zr, Hf, V, Nb, Ta, Cr, Mo, W, Mn, Tc, Re, Fe, Ru, Os, Co, Rh, Ir, Ni, Pd, Pt, Cu, Ag, Au, Zn, Cd, Pb, La, Ce, Pr, Nd, Pm, Sm, Eu, Gd, Tb, Dy, Ho, Er, Tm, Yb, Lu, or any combination thereof.

43. The method of claim 33, wherein an electronegative element comprises N, O, S, F, Cl, Br, or I.

44. A method, comprising:
placing a layer of semiconducting material into contact with a second layer of material that comprises an electronegative element; and
effecting disposition of at least some of the electronegative element within the layer of semiconducting material, forming an amorphous layer.

45. The method of claim 44, further comprising thermal annealing, ion bombardment, plasma treatment, or any combination thereof.

46. The method of claim 44, wherein the composition of the amorphous layer is characterized as SC[Oₓ], SC[N_{y}], or SC[OₓN_{z}], wherein SC comprises a electrically semiconducting composition and wherein x is in the range of between about 0.01 and less than 2, wherein y is in the range of between about 0.01 and less than 4/3, and wherein z is in the range between about 0.01 and less than (4−2x)/3.

47. The method of claim 44, wherein the amorphous layer further comprises a metal

48. A method, comprising:
contacting an electrode that comprises an electronegative element with a layer of semiconducting material; and
effecting disposition of at least some of the electronegative element within the layer of semiconducting material, forming an amorphous layer.

49. The method of claim 48, further comprising thermal annealing, ion bombardment, plasma treatment, or any combination thereof.

50. The method of claim 48, wherein the composition of the amorphous layer is characterized as SC[Oₓ], SC[N_{y}], or SC[OₓN_{z}], wherein SC comprises a electrically semiconducting composition and wherein x is in the range of between about 0.01 and less than 2, wherein y is in the range of between about 0.01 and less than 4/3, and wherein z is in the range between about 0.01 and less than (4−2x)/3.

51. The method of claim 48, wherein the amorphous layer further comprises a metal

52. The method of claim 48, wherein the semiconducting material comprises an elemental semiconductor, a group IV compound semiconductor, a group III-V semiconductor, a group II-VI semiconductor, a group IV-VI semiconductor, a group II-V semiconductor, or any combination thereof.

53. A device according to claim 1, wherein the semiconducting composition is a doped semiconductor of n-type or p-type.
